(19) United States
(12) Patent Application Publication
(10) Pub. No.: US 2026/0223614 A1
(43) Pub. Date: Jul. 30, 2026

(54) METHOD FOR SELECTIVE WET ETCHING OF SILICON NITRIDE FILMS

(71) Applicant: ZHEJIANG NORMAL UNIVERSITY, Jinhua (CN)

(72) Inventors: CLARENCE AUGUSTINE TECK HUO TEE, Jinhua (CN); BURHANUDDIN YEOP MAJLIS, Selangor (MY); WEY PING YEO, Selangor (MY); MIMIWATY MOHD NOOR, Selangor (MY); GANDI SUGANDI, Selangor (MY)

(21) Appl. No.: 19/076,085

(22) Filed: Mar. 11, 2025

(30) Foreign Application Priority Data
Jan. 24, 2025 (CN) 202510117592.3

(51) Int. Cl. H01L 21/311

(52) U.S. Cl. CPC H10P 50/283; H10P 50/73

(57) ABSTRACT

Disclosed is a method for selective wet etching of silicon nitride films. The method includes: preparing a Si₃N₄ wafer, where the Si₃N₄ wafer is provided with a film composed of Si₃N₄, preparing and coating a photoresist material on the Si₃N₄ film, performing selective wet etching of the Si₃N₄ wafer with the Si₃N₄ film at low temperatures, cleaning the etched wafer, and removing a photoresist mask from the cleaned wafer. The photoresist is used as a mask, a window of a desired pattern shape is first photolithographed on a photoresist film, and then the Si₃N₄ film is etched through the wet etching, which achieves higher etching quality and precision, increases an etching rate at low temperatures and overcomes the above defects of mask stripping and under-etching.

### CROSS-REFERENCE TO RELATED APPLICATIONS

This application claims priority to Chinese Patent Application No. 202510117592.3, filed on Jan. 24, 2025, which is hereby incorporated by reference in its entirety.

### TECHNICAL FIELD

The present disclosure relates to the technical field of etching silicon nitride films, and in particular to the technical field of wet etching of silicon nitride in a mixed solution of buffered hydrofluoric acid (BHF)/ammonium fluoride (NH₄F).

### BACKGROUND

Currently known methods for etching silicon nitride (Si₃N₄) films include plasma etching, wet etching and the like. Acidic solutions are usually used for the wet etching, and hydrofluoric acid (HF), buffered hydrofluoric acid (BHF), or phosphoric acid (H₃PO₄) can be used as an etchant. A photoresist material is usually used as a mask for the wet etching of Si₃N₄, and is soaked in an HF or BHF solution usually at room temperature. This process is relatively simple and cost-effective. However, selective etching of Si₃N₄ films is defective when a photoresist mask is used, because the photoresist mask is easily stripped after 2 h of etching, and also there exists the defect of under-etching.

The defects of stripping and under-etching are primarily caused by prolonged use of the photoresist as a mask layer for Si₃N₄ etching, which leads to instability of the photoresist. A long etching process may cause diffusion of the etchant into a photoresist layer, swelling of the photoresist, and exposing of areas that are not protected by the mask. This may lead to corrosion of a Si₃N₄ layer and even a silicon substrate.

In a further aspect, the plasma etching with the photoresist as a mask achieves better etching results. However, this process is complex and costly, and requires high process precision.

The U.S. Patent No. U.S. Pat. No. 8,741,168B2 discloses a method for etching silicon nitride films, and the method includes steps of supplying an anti-etching material and etching a silicon nitride film. The supplying an anti-etching material includes supplying the anti-etching material to a processing surface, and the processing surface includes a surface of the silicon nitride film and a surface of a non-etching film, where a material of the non-etching film is different from that of the silicon nitride film. The etching includes etching the silicon nitride film by using an etchant in a state of forming the anti-etching material relatively more densely on the surface of the non-etching film than the surface of the silicon nitride film. Although an anti-etching material is mentioned in this patent, a self-assembled monolayer (SAM) is used as a mask instead of a photoresist mask, which is another type of mask material for creating wafer patterns.

The European patent with the publication No. 0590876A2 discloses an etching method for integrated circuit manufacturing. According to the method, a layer containing an Si₃N₄ or silicon material is etched, the material is placed on silicon oxide, and a wet bath containing H₃PO₄, BHF or nitric acid is used for etching. The present disclosure aims to improve selectivity of the wet etching by combining the three etchants (H₃PO₄, BHF and nitric acid) and supplementing BHF and nitric acid over a certain period. Although the present disclosure can improve the selectivity of the wet etching, a photoresist mask layer is not used.

In view of the above situations, a low-cost, time-saving method for selective wet etching of Si₃N₄ films is needed to overcome the above defects of mask stripping and under-etching.

### SUMMARY

In order to solve the problems in the prior art, an objective of the present disclosure is to provide a method for selective wet etching of silicon nitride films, and use of a photoresist as a mask increases an etching rate at low temperatures and overcomes the above defects of mask stripping and under-etching.

To achieve the above objective, the present disclosure provides a method for selective wet etching of silicon nitride films, and the method includes the following steps:
S1, providing a Si₃N₄ wafer, where the Si₃N₄ wafer is provided with a film composed of Si₃N₄;
S2, removing impurities on the Si₃N₄ wafer using an organic solvent;
S3, processing the Si₃N₄ wafer with a buffered hydrofluoric acid (BHF)/ammonium fluoride (NH₄F) solution;
S4, dehydrating the Si₃N₄ wafer at a temperature of 120° C. to 150° C.;
S5, coating the dehydrated Si₃N₄ wafer with a photoresist material as a mask for the film, then heating the wafer with the mask to 90° C.-95° C., and performing photolithography on the heated mask while exposing same to ultraviolet light;
S6, heating the exposed wafer with the mask to 110° C.-120° C.;
S7, placing the wafer in a BHF or NH₄F solution at a temperature of 40° C. to 80° C., and etching unmasked areas of the film; and
S8, cleaning and removing the residual photoresist material from the etched wafer.

Preferably, the organic solvent mentioned in the S2 includes any one or any combination of acetone, deionized water, and isopropanol.

Preferably, the placing the wafer in a BHF or NH₄F solution at a temperature of 80° C. in the S7 includes etching the exposed Si₃N₄ film with the mask.

Preferably, time of the etching is 1 min.

The method for selective wet etching of silicon nitride films of the present disclosure has the following beneficial effects: in the present disclosure, the photoresist is used as a mask, a window of a desired pattern shape is first photolithographed on a photoresist film, and then the Si₃N₄ film is etched through the wet etching, which achieves higher etching quality and precision, increases an etching rate at low temperatures and overcomes the above defects of mask stripping and under-etching.

An advantage of the present disclosure lies in that after applying of the photoresist mask on the Si₃N₄ film, the Si₃N₄ wafer is heated to 110° C.-120° C. for 5 to 10 min, to increase adhesion of a photoresist mask layer to the Si₃N₄ wafer.

Another advantage of the present disclosure lies in that the temperature of the BHF/NH₄F solution maintains between 40° C. and 80° C., which increases the etching rate by etching the Si₃N₄ film in a short period, thereby preventing stripping of the photoresist mask layer from the Si₃N₄ film and allowing the etchant to diffuse through the Si₃N₄ film and a substrate.

The features and advantages of the present disclosure will be described in detail with reference to the examples and the accompanying drawings.

### BRIEF DESCRIPTION OF DRAWINGS

FIG. 1 is a schematic diagram of Si of the present disclosure.

FIG. 2 is a schematic diagram of coating a Si₃N₄ wafer with a photoresist material in S5 of the present disclosure.

FIG. 3 is a schematic diagram of performing photolithography on a heated mask in S5 of the present disclosure.

FIG. 4 is a schematic diagram of processing of a mask through photolithography of the present disclosure.

FIG. 5 is a schematic diagram of a mask processed through photolithography of the present disclosure.

FIG. 6 is a schematic diagram of etching a film in S7.

FIG. 7 is a schematic diagram of an etched wafer in S7.

FIG. 8 is a schematic diagram of a wafer after cleaning and removing residual photoresist material in S8.

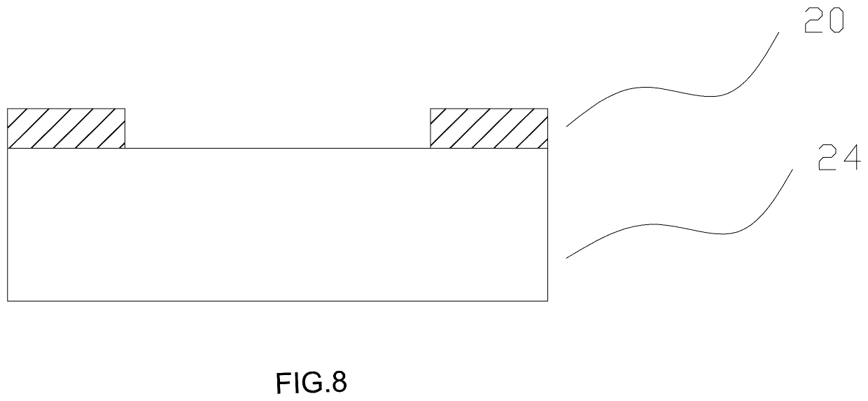

FIG. 9 is a schematic diagram of a wafer according to an example of the present disclosure, where FIG. 3a is a schematic diagram of a wafer in a photolithography process, FIG. 3b is a wafer before removing a photoresist material mask, and FIG. 3c is a wafer after removing a photoresist material mask.

FIG. 10 is a graph of a relationship between a temperature of a buffered hydrofluoric acid (BHF) solution and an etching rate according to data of an example of the present disclosure.

Reference numerals in the figures: 20—film, 22—photoresist material, 24—Si₃N₄ wafer, 26—BHF/NH₄F solution, 30—standard photolithography process, 34—container, and 36—support.

### DESCRIPTION OF EMBODIMENTS

For making the objectives, technical solutions and advantages of the present disclosure clearer, the present disclosure will be described in further detail below with reference to the accompanying drawings and the examples. It should be understood that the specific examples described herein are merely illustrative of the present disclosure and are not intended to limit the present disclosure. In addition, in the following descriptions, descriptions of well-known structures and technologies are omitted in order to avoid unnecessarily obscuring the concepts of the present disclosure.

In the descriptions of the present disclosure, it should be noted that when an element is referred to as being “fixed to” or “arranged on” another element, the element may be directly or indirectly on another element. When an element is referred to as being “connected to” another element, the element may be directly or indirectly connected to another element.

In the descriptions of the present disclosure, it should be noted that the terms “center”, “length”, “width”, “thickness”, “upper”, “lower”, “front”, “back”, “left”, “right”, “vertical”, “horizontal”, “top”, “bottom”, “inner”, “outer”, etc. indicate orientation or position relations based on those shown in the accompanying drawings, or of common placement when the product of the present disclosure is used, which are only for ease of description of the present disclosure and for simplicity of description, and are not intended to indicate or imply that the referenced device or element must have a particular orientation and be constructed and operated in a particular orientation, and thus may not be construed as a limitation on the present disclosure. Moreover, the terms “first”, “second”, “third”, etc. are used merely to distinguish between descriptions and may not be construed as indication or implication of relative importance. Thus, a feature defined with “first” and “second” may explicitly or implicitly include one or more of the features. In the description of the present disclosure, “a plurality of” means two or more, unless expressly specified otherwise. “Several” means one or more, unless expressly specified otherwise.

In the description of the present disclosure, it should be further noted that, unless otherwise clearly specified, meanings of terms “arrange”, “mount”, “connected” and “connect” should be understood in a board sense. For example, the connection may be a fixed connection, a detachable connection, an integral connection; may be a mechanical connection or an electrical connection; may be a direct connection or an indirect connection by using an intermediate medium; or may be intercommunication between two components. For those of ordinary skill in the art, the specific meanings of the above terms in the present disclosure may be understood according to specific circumstances.

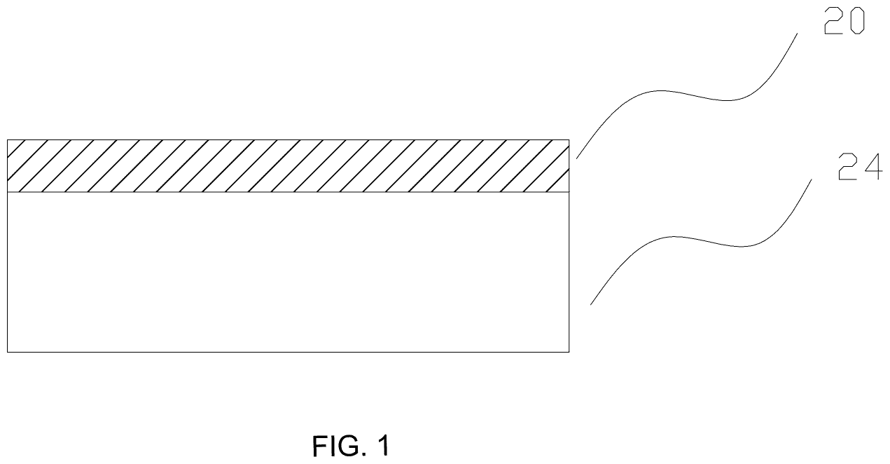

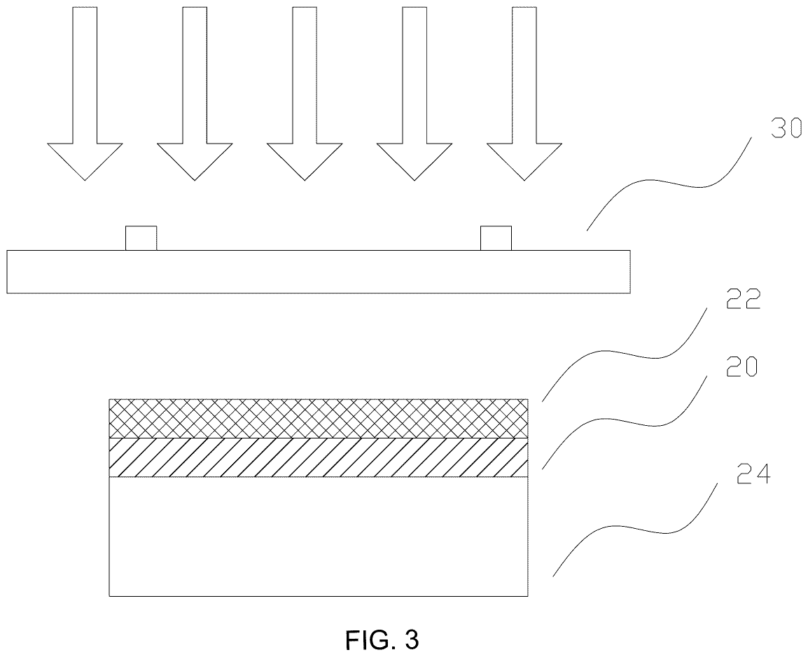

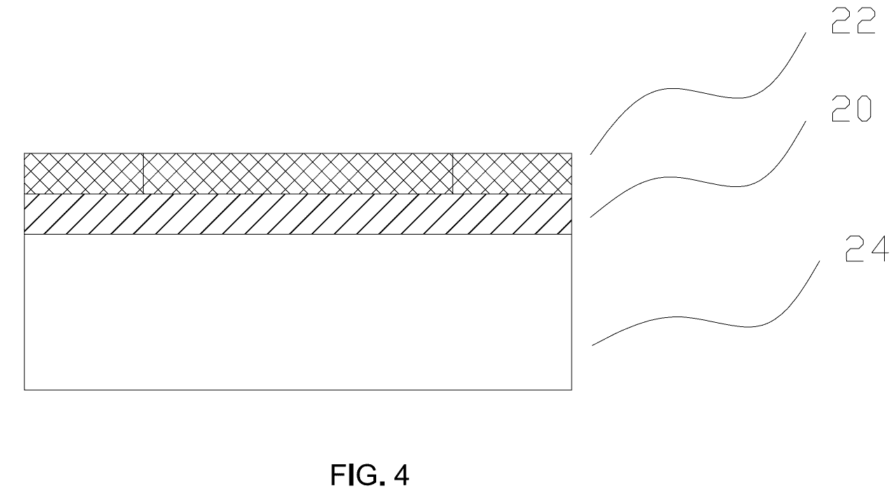

With reference to FIGS. 1-4, the present disclosure relates to a method for wet etching of a silicon nitride (Si₃N₄) film 20 on a Si₃N₄ wafer 24 at low temperatures in a buffered hydrofluoric acid (BHF)/ammonium fluoride (NH₄F) solution 26 through a window on a photoresist material 22, and the method specifically includes the following steps:

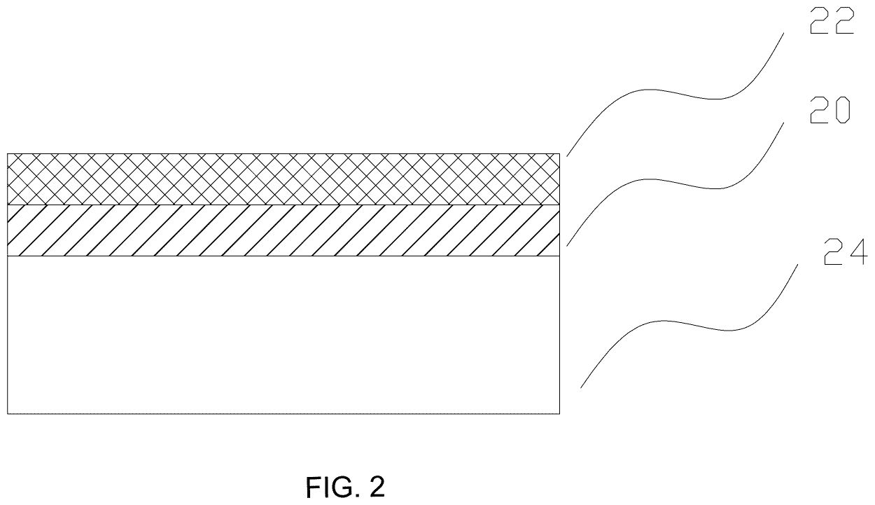

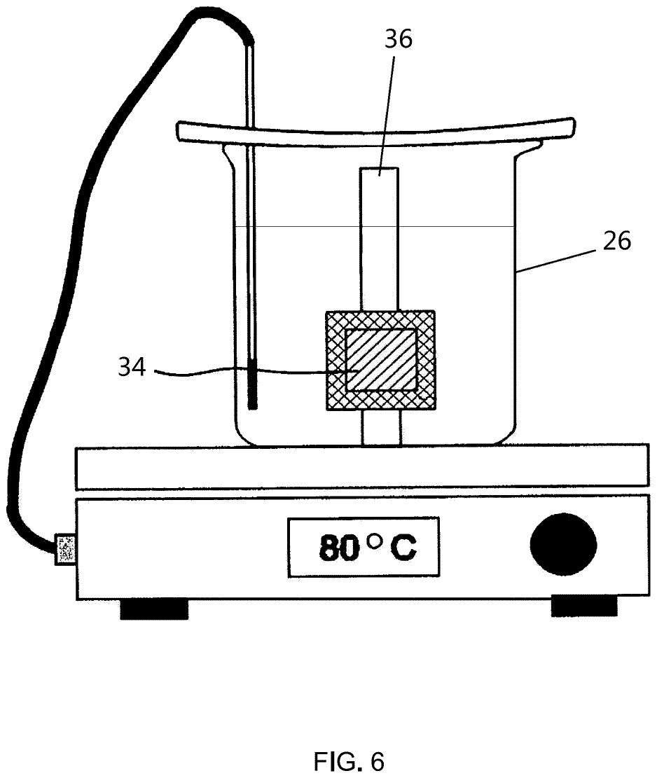

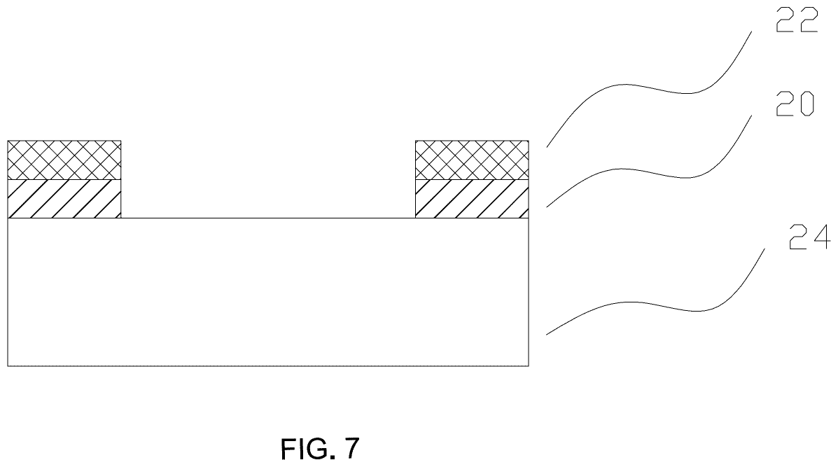

I. prepare the Si₃N₄ wafer 24, where the Si₃N₄ wafer 24 is provided with the film 20 composed of Si₃N₄, as shown in FIG. 1; II. prepare and coat the photoresist material 22 on the Si₃N₄ film 20, as shown in FIG. 2; III. perform selective wet etching of the Si₃N₄ wafer 24 with the Si₃N₄ film 20 at low temperatures, as shown in FIGS. 2-5; IV. clean the etched wafer, as shown in FIG. 6; and V. remove a photoresist mask from the cleaned wafer, as shown in FIG. 7.

SI involves a wafer preparation process, where the Si₃N₄ wafer 24 is first cleaned in an organic solvent, such as acetone, isopropanol (IPA), and deionized water (DI). Then, the Si₃N₄ wafer 24 is processed with the BHF/NH₄F solution for a short period of time, after which the wafer is placed on a hotplate and baked at a temperature of 120° C. to 150° C. for 30 min to remove moisture from the wafer.

With reference to FIGS. 2-4, the photoresist material 22 is coated on the Si₃N₄ wafer 24, and then the photoresist material 22 is exposed through a standard photolithography process to define a pattern on the Si₃N₄ wafer 24 and increase adhesion of the photoresist material 22. The fresh photoresist material 22 (such as fresh AZ 4620) as a mask is coated on the Si₃N₄ film 20 of the Si₃N₄ wafer 24, and then accelerated spin coating is performed at a speed of 2000-3000 rpm on a wafer spin coater to ensure uniform coating of the photoresist. The coated Si₃N₄ wafer is then pre-baked on the hotplate at a temperature of 90° C. to 95° C. for heating for 2-3 min. Then the coated Si₃N₄ wafer is exposed to ultraviolet light through a standard Mask Aligner photolithography apparatus, and exposure time is 80-90 sec. The exposed Si₃N₄ wafer is then developed in a standard AZ4620 developer, and a dilution ratio of the developer is 1:3 (AZ400:DI). The developed Si₃N₄ wafer is baked again on the hotplate at a temperature of 110° C. to 120° C. for 5 min.

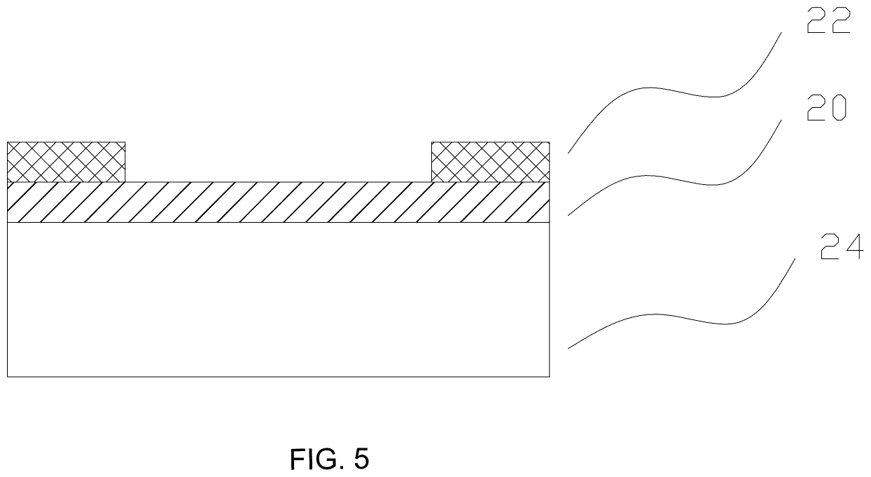

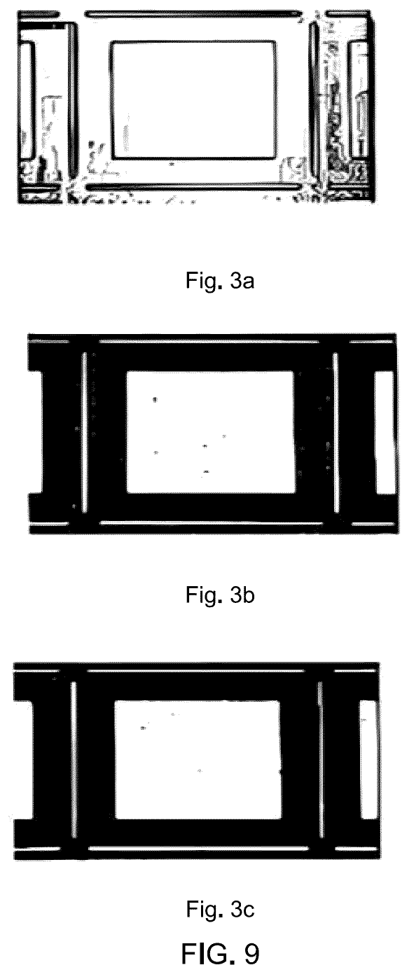

With reference to FIGS. 5 and 9, the method involves etching the Si₃N₄ film 20 with the mask, and the mask has already been correspondingly patterned through the foregoing photolithography process. The wafer processed through the photolithography process is soaked in a hot, fresh BHF/NH₄F solution 26 at a temperature of 40° C. to 80° C., and the temperature can be specifically adjusted based on a desired etching rate.

Specifically, the etching the Si₃N₄ film 20 includes the following steps: i. prepare the BHF/NH₄F solution 26 with a concentration ratio of 10:1; ii. pour 150 mL of the BHF/NH₄F solution 26 into a container 34; iii. prepare a support 36 to fix the Si₃N₄ wafer 24; iv. set, control and maintain a temperature of the BHF/NH₄F solution 26 in a range from 40° C. to 80° C.; v. maintain atmospheric pressure at 1 atm throughout the etching process; and vi. fix the Si₃N₄ wafer 24 on the support and soak same in the BHF/NH₄F solution 26 for required etching time to etch the mask-exposed Si₃N₄ film 20 on the Si₃N₄ wafer 24.

Siv includes typical cleaning of the etched Si₃N₄ wafer, where the etched Si₃N₄ wafer is cleaned with DI to remove residual BHF/NH₄F from the etched Si₃N₄ wafer. Then, nitrogen gas is used to dry the etched Si₃N₄ wafer.

Sv involves removing the residual photoresist material 22 from the etched Si₃N₄ wafer using acetone, IPA, or DI, and then drying the etched Si₃N₄ wafer with nitrogen gas.

The present disclosure will be further described in detail below through several non-limited experimental examples.

### Example 1

In this example, a total of five samples of the Si₃N₄ wafer 24 were prepared, the Si₃N₄ film 20 of each sample was subjected to wet etching in a BHF/NH₄F solution for 1 min at etching temperatures of 40° C., 50° C., 60° C., 70° C., and 80° C. respectively.

Each of the Si₃N₄ wafers 24 was cleaned with acetone, isopropanol (IPA), and deionized water (DI), and the Si₃N₄ wafers 24 were prepared. Then, the Si₃N₄ wafer 24 was processed with a BHF/NH₄F solution for a short period of time, and was subsequently baked on a hotplate at a temperature of 120° C. to 150° C. for 30 min to remove moisture from the wafer.

The Si₃N₄ film 20 of the Si₃N₄ wafer 24 was coated with a fresh photoresist material 22 (AZ 4620) as a mask, and accelerated spin coating was performed at a speed of 2000 rpm on a wafer spin coater, to ensure uniform surface thickness distribution of a mask layer. Then, the Si₃N₄ wafer 24 as shown in FIG. 2 was pre-baked on the hotplate at a temperature of 90° C. to 95° C. for 2-3 min. Then a Mask Aligner photolithography apparatus was used to expose the mask of the Si₃N₄ wafer 24 to ultraviolet light under conditions of a standard photolithography process 30 and a desired configuration, and exposure time is 80-90 sec. The exposed photoresist was developed in a standard AZ4620 developer (a dilution ratio of AZ400:DI is 1:3). Then the exposed masked Si₃N₄ wafer 24, as shown in FIG. 5, was heated on the hotplate for 5 min at a temperature of 110° C. to 120° C.

With reference to FIG. 6, 150 mL of a BHF solution was then prepared at a concentration ratio of 10:1 and poured into a Teflon beaker. The exposed masked Si₃N₄ wafer 24 was fixed on a Teflon support and contacted with the BHF/NH₄F solution at 40° C. for 3 min of etching, and the unmasked Si₃N₄ film 20 was etched.

With reference to FIG. 7, after 3 min of etching, the etched Si₃N₄ wafer 24 was cleaned with DI to remove the BHIF solution. Then, the cleaned etched Si₃N₄ wafer 24 was dried with nitrogen gas. Finally, the residual photoresist material 22 from the cleaned etched Si₃N₄ wafer 24 using acetone, IPA, or DI, and then the etched Si₃N₄ wafer was dried with nitrogen gas.

The experiment was repeated four times at etching temperatures of 50° C., 60° C., 70° C., and 80° C. respectively, with etching time of 1 min each time.

### Example 2

In this example, five samples of the Si₃N₄ wafer 24 were also prepared, the Si₃N₄ film 20 of each sample was subjected to wet etching in a BHF/NH₄F solution for 1 min at etching temperatures of 40° C., 50° C., 60° C., 70° C., and 80° C. respectively. The difference between this example and Example 1 lies in that etching time in this example was maintained at 3 min each time.

### Example 3

In this example, five samples of the Si₃N₄ wafer 24 were also prepared, the Si₃N₄ film 20 of each sample was subjected to wet etching in a BHF/NH₄F solution for 1 min at etching temperatures of 40° C., 50° C., 60° C., 70° C., and 80° C. respectively. The difference between this example and Example 1 lies in that etching time in this example was maintained at 5 min each time.

In each of the three examples, the Si₃N₄ wafers 24 with a thickness of 700 μm were used as substrates, the Si₃N₄ film 20 with a thickness of 200 nm was used, and the photoresist material 22 was used as a mask. Then the wafer was etched in the BHF/NH₄F solution 42, and the BHF/NH₄F solution was used as an etchant.

A total of 15 samples of the Si₃N₄ wafers 20 were used in the experiments, with experimental results shown in Table 1 below. The samples were etched in the BHF/NH₄F solutions 42 at different temperatures (40° C., 50° C., 60° C., 70° C., 80° C.) and different etching time (1 min, 3 min, and 5 min).

| | Etching rate (nm/min) | | | |
|---|---|---|---|---|
| Temperature | 1 min | 3 min | 5 min | Average |
| (° C.) | (Example 1) | (Example 2) | (Example 3) | (nm/min) |
| 40 | 2.2 | 2.2 | 2.0 | 2.13 |
| 50 | 4.6 | 4.6 | 4.6 | 4.58 |
| 60 | 5.7 | 8.7 | 10.4 | 8.27 |
| 70 | 16.2 | 17.9 | 23.0 | 19.02 |
| 80 | 43.4 | 39.8 | 39.6 | 40.94 |

Results in the above table indicate that the etching rates of the Si₃N₄ films in the BHF/NH₄F solutions at temperatures of 40° C., 50° C., 60° C., 70° C., and 80° C. are 2.13, 4.58, 8.27, 19.02, and 40.94 nm/min, respectively.

In Example 1, the etching rates of the Si₃N₄ films in the BHF/NH₄F solutions 42 subjected to 1 min of wet etching at temperatures of 40° C., 50° C., 60° C., 70° C., and 80° C., are 2.2, 4.6, 5.7, 16.2, and 43.4 nm/min respectively, depending on the temperatures of the BHF/NH₄F solutions 42.

In Example 2, the etching rates of the Si₃N₄ films in the BHF/NH₄F solutions 42 subjected to 3 min of wet etching at temperatures of 40° C., 50° C., 60° C., 70° C., and 80° C., are 2.2, 4.6, 8.7, 17.9, and 39.8 nm/min respectively, depending on the temperatures of the BHF/NH₄F solutions 42.

In Example 3, the etching rates of the Si₃N₄ films in the BHF/NH₄F solutions 42 subjected to 3 min of wet etching at temperatures of 40° C., 50° C., 60° C., 70° C., and 80° C., are 2.0, 4.6, 10.4, 23.0, and 39.6 nm/min respectively, depending on the temperatures of the BHF/NH₄F solutions 42.

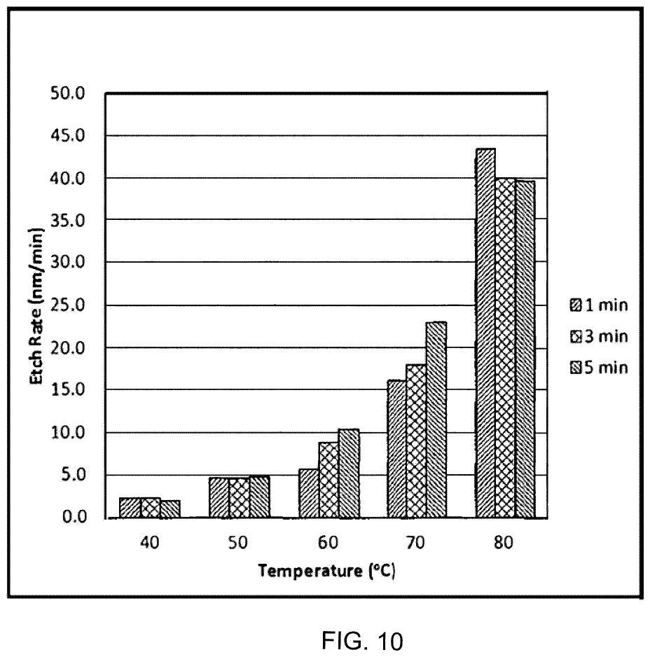

FIG. 10 shows results of the three experiments correspond to Table 1, and it is concluded that as the temperature of the etchant (the BHF/NH₄F solution 42) increases, the etching rate of the Si₃N₄ film 20 increases. The etching rate is optimal after 1 min of wet etching at 80° C., reaching 43.4 nm/min.

To sum up, the results of the three examples further demonstrate that the wet etching method of the present disclosure has significant effects over any conventional room-temperature wet etching method that may require up to 4 h of wet etching. Moreover, a rapid etching window is generated when the photoresist is used as a mask.

It should be noted that the above examples have been described herein, but are not intended to limit the patent scope of the present disclosure. Therefore, changes and modifications of made to the example described herein based on the innovative concepts of the present disclosure, or any equivalent structure or equivalent process transformation made by using the description of the present disclosure and the contents of the accompanying drawings, with the above technical solution directly or indirectly used in other related technical fields, are all included in the protection scope of the present disclosure.

What is claimed is:

1. A method for selective wet etching of silicon nitride films, comprising the following steps:
S1, providing a Si₃N₄ wafer, wherein the Si₃N₄ wafer is provided with a film composed of Si₃N₄;
S2, removing impurities on the Si₃N₄ wafer using an organic solvent;
S3, processing the Si₃N₄ wafer with a buffered hydrofluoric acid (BHF)/ammonium fluoride (NH₄F) solution;
S4, dehydrating the Si₃N₄ wafer at a temperature of 120° C. to 150° C.;
S5, coating the dehydrated Si₃N₄ wafer with a photoresist material as a mask for the film, then heating the wafer with the mask to 90° C.-95° C., and performing photolithography on the heated mask while exposing same to ultraviolet light;
S6, heating the exposed wafer with the mask to 110° C.-120° C.;
S7, placing the wafer in a BHF or NH₄F solution at a temperature of 40° C. to 80° C., and etching unmasked areas of the film; and
S8, cleaning and removing the residual photoresist material from the etched wafer.

2. The method for selective wet etching of silicon nitride films according to claim 1, wherein the organic solvent mentioned in the S2 comprises any one or any combination of acetone, deionized water, and isopropanol.

3. The method for selective wet etching of silicon nitride films according to claim 1, wherein the placing the wafer in a BHF or NH₄F solution at a temperature of 80° C. in the S7 comprises etching the exposed Si₃N₄ film with the mask.

4. The method for selective wet etching of silicon nitride films according to claim 3, wherein time of the etching is 1 min.
